(19) United States
(12) Patent Application Publication
(10) Pub. No.: US 2026/0268035 A1
(43) Pub. Date: Sep. 10, 2026

(54) SIMULATION DEVICE, SIMULATION METHOD, AND PROGRAM

(71) Applicant: NEC Corporation, Tokyo (JP)

(72) Inventors: Akihiro YATABE, Tokyo (JP); Yukihiro ABE, Tokyo (JP)

(73) Assignee: NEC Corporation, Tokyo (JP)

(21) Appl. No.: 19/164,041

(22) PCT Filed: Mar. 28, 2023
(86) PCT No.: PCT/JP2023/012466

§ 371 Date: Sep. 10, 2025

(51) Int. Cl. G06F 30/20; G06F 17/16

(52) U.S. Cl. CPC G06F 30/20; G06F 17/16

(57) ABSTRACT

A simulation device includes: a tensor contraction calculation unit that performs a contraction calculation in a tensor network corresponding to a quantum gate operation on the basis of the states of qubits in a quantum circuit and information indicating a quantum gate operation to be applied to the qubits; a matrix product state composition unit that composes a matrix product state from the states of the qubits obtained as a result of the contraction calculation by the tensor contraction calculation unit; and a low-rank approximation calculation unit that performs a low-rank approximation for each of a plurality of quantum gate operations lumped together when the matrix product state composition unit composes the matrix product state.

### TECHNICAL FIELD

The present invention relates to a simulation device, a simulation method, and a program.

### BACKGROUND ART

Unlike conventional computers, quantum computers are computers that operate based on quantum mechanical properties. Recent social problems require handling enormous amounts of data, performing complex calculations, and similar tasks at high speed, and quantum computers are expected as a means having a possibility of being able to meet these demands. In fact, in order to solve actual problems, developments are actively being made in a type of quantum computer called a gate-based quantum computer to increase the number of qubits. The gate-based quantum computer is a quantum computer that performs quantum computation by a quantum circuit in which quantum gates are arranged. The quantum circuit in this case is hardware that directly makes use of quantum mechanical phenomena.

In parallel with the development of quantum computers, research and development are being conducted to accelerate simulations on conventional computers inspired by computation using quantum computers. Such efforts include performing simulations of computation by a quantum computer (quantum circuit simulation) using a conventional computer. This is being carried out to understand the operation of quantum computers and develop quantum algorithms.

An example of the methods used for simulating a quantum computer is the tensor network method. A tensor network is a network connected by operations called “contraction” associated with multi-dimensional arrays called tensors. Tensors include vectors, which are one-dimensional arrays, and matrices, which are two-dimensional arrays. Vectors can be regarded as one-dimensional tensors. Matrices can be regarded as two-dimensional tensors. In the sense that the dimension of matrices is increased, tensors are generalizations of matrices. In addition, normal numbers called scalars can be regarded as zero-dimensional tensors.

FIG. 1 illustrates examples of a tensor contraction operation and a tensor network graph. An example of a contraction operation is shown on the upper side of FIG. 1, and an example of a tensor network graph is shown on the lower side of FIG. 1. Contraction involves summing over indices of tensors. For example, in a tensor network graph like the one shown in the lower part of FIG. 1, nodes T₁, T₂, T₃, T₄ each represent a tensor. Edges i₁, i₂, . . . , is extending from the nodes represent the indices of the respective tensors. The number of edges represents the dimension of each tensor. The tensor network graph shown in the lower part of FIG. 1 corresponds to the expression of a contraction operation shown in the upper part of FIG. 1. This graph contracts i₁, i₂, i₃, i₄, and i₅. In a tensor network graph, tensor contraction is indicated by the edges connecting the nodes.

To simulate a quantum computer using a tensor network, a quantum circuit representing computation by the quantum computer is regarded as a tensor network of states and gate operators, and the simulation is achieved by performing contraction with respect to the indices connected in the network.

FIG. 2 is a diagram illustrating an example of how to add indices to tensors when a quantum circuit is regarded as a tensor network. In the example of a quantum circuit illustrated in FIG. 2, quantum computation starts from the initial state on the leftmost side, proceeds to the right as quantum gate operations are sequentially applied to the qubits, and the state is observed at the rightmost stage after the quantum gate operations are completed. In a case where this series of operations is calculated based on a tensor network, the quantum states and the gates are regarded as nodes in the tensor network graph, and the lines connecting quantum states with gates and the lines connecting gates with each other are regarded as edges. In FIG. 2, symbols such as i₁ indicated on these lines are considered as indices of tensors.

In a simulation of a quantum circuit using a tensor network, calculation can be exactly performed, but the calculation can also be performed approximately by combining a matrix product state with low-rank approximation, as is well known in the field of tensor networks (e.g., NPL 1). As the number of qubits increases, the number of quantum states to be handled increases exponentially, and the amount of computation increases similarly. Therefore, approximate computation is particularly useful in a case where the computation is performed using a general personal computer (PC) or the like, or in a case where the accuracy requirement is not so high.

The present invention discusses this approximate computation of a quantum circuit in which a matrix product state and a low-rank approximation are used.

On the other hand, PTL 1 and PTL 2 disclose examples of known techniques related to simulations that do not approximate quantum circuits using tensor networks. The technique described in PTL 1 includes a method in which, in a simulation of an n-qubit quantum circuit, when a k-qubit gate (k<n) is applied, the indices of n qubits representing a state are appropriately rearranged to group variables included in the qubit gate, thereby reducing the amount of computation of matrix multiplication corresponding to a contraction operation. The technique described in PTL 2 includes a method in which, when a matrix representing an operation by a single qubit gate or a combined operation by a plurality of qubit gates contains only diagonal elements, the amount of computation of the tensor network contraction can be reduced, since no computation is required for the off-diagonal elements.

### CITATION LIST

### Patent Literature

PTL 1: JP 2022-3501 A
PTL 2: JP 2021-520546 A

### Non Patent Literature

NPL 1: “Quantum Software Pilot Lecture: Data Compression in Computational Science and Quantum Computing”, [online], [Accessed on Nov. 17, 2022], Internet <URL: https://github.com/utokyo-qsw/data-compression>

### SUMMARY OF INVENTION

### Technical Problem

However, in a case where a simulation of a quantum circuit is performed by combining tensor contraction, matrix product states, and low-rank approximation, low-rank approximation is performed every time a multi-qubit gate is applied. Therefore, if a large number of quantum gate operations are performed, the accuracy of the simulation decreases.

### Solution to Problem

According to one aspect of the invention, a simulation device includes: a tensor contraction operation unit that performs a contraction operation in a tensor network corresponding to a quantum gate operation, based on a state of a qubit included in a quantum circuit and information indicating a quantum gate operation applied to the qubit; a matrix-product-state construction unit that constructs a matrix product state from a state of a qubit obtained by a contraction operation by the tensor contraction operation unit; and a low-rank approximation computation unit that performs low-rank approximation for each group of a plurality of quantum gate operations when the matrix-product-state construction unit constructs a matrix product state.

According to one aspect of the invention, a simulation device includes: a simulation result comparison unit that compares a plurality of simulation results that use different approximation methods in an approximate simulation of a quantum circuit whose starting state is a pure state, the comparison being based on the proximity of each simulation result to a pure state; and a simulation result output unit that outputs the simulation result closest to a pure state among the plurality of simulation results based on a result of comparison by the simulation result comparison unit.

According to one aspect of the invention, a simulation method includes: a tensor contraction operation step of performing a contraction operation in a tensor network corresponding to a quantum gate operation, based on a state of a qubit included in a quantum circuit and information indicating a quantum gate operation applied to the qubit; a matrix-product-state construction step of constructing a matrix product state from a state of a qubit obtained by a contraction operation by the tensor contraction operation step; and a low-rank approximation computation step of performing low-rank approximation for each group of a plurality of quantum gate operations when the matrix-product-state construction step constructs a matrix product state.

According to one aspect of the invention, a simulation method includes: a simulation result comparison step of comparing a plurality of simulation results that use different approximation methods in an approximate simulation of a quantum circuit whose starting state is a pure state, the comparison being based on the proximity of each simulation result to a pure state; and a simulation result output step of outputting the simulation result closest to a pure state among the plurality of simulation results based on a result of comparison by the simulation result comparison step.

According to one aspect of the invention, a program causes a computer to execute: a tensor contraction operation step of performing a contraction operation in a tensor network corresponding to a quantum gate operation, based on a state of a qubit included in a quantum circuit and information indicating a quantum gate operation applied to the qubit; a matrix-product-state construction step of constructing a matrix product state from a state of a qubit obtained by a contraction operation by the tensor contraction operation step; and a low-rank approximation computation step of performing low-rank approximation for each group of a plurality of quantum gate operations when the matrix-product-state construction step constructs a matrix product state.

According to one aspect of the invention, a program causes a computer to execute: a simulation result comparison step of comparing a plurality of simulation results that use different approximation methods in an approximate simulation of a quantum circuit whose starting state is a pure state, the comparison being based on the proximity of each simulation result to a pure state; and a simulation result output step of outputting the simulation result closest to a pure state among the plurality of simulation results based on a result of comparison by the simulation result comparison step.

### Advantageous Effects of Invention

According to the present invention, when a quantum circuit is approximately simulated based on a tensor network, it is possible to mitigate the influence of decrease in simulation accuracy due to approximation.

### BRIEF DESCRIPTION OF DRAWINGS

FIG. 1 shows examples of a tensor contraction operation and a tensor network graph.

FIG. 2 is a diagram illustrating an example of how to add indices to tensors when a quantum circuit is regarded as a tensor network.

FIG. 3 is a diagram illustrating an example of a tensor network graph corresponding to performing singular value decomposition to construct a matrix product state.

FIG. 4 is a diagram illustrating an example of a tensor network graph corresponding to performing a 1-qubit gate operation on a matrix product state.

FIG. 5 is a diagram illustrating an example of a tensor network graph corresponding to performing a 2-qubit gate operation on a matrix product state.

FIG. 6 is a diagram for explaining the decrease in simulation accuracy in the case where low-rank approximation is performed every time a multi-qubit gates operation is performed.

FIG. 7 is a diagram illustrating an outline of a first computation method according to an example embodiment of the present invention.

FIG. 8 is a diagram illustrating an outline of a method of performing low-rank approximation from matrix product states without performing quantum gate operations, according to an example embodiment of the present invention.

FIG. 9 is a diagram illustrating an outline of a second computation method according to an example embodiment of the present invention.

FIG. 10 is a block diagram illustrating an example of the configuration of a quantum circuit simulation device 100 according to an example embodiment of the present invention.

FIG. 11 is a diagram illustrating an example of a flow of processing based on a simulation method according to an example embodiment of the present invention.

FIG. 12 is a diagram illustrating an example of a flow of processing based on a computation method in a case where low-rank approximation is performed for each quantum gate operation according to an example embodiment of the present invention.

FIG. 13 is a diagram illustrating an example of a flow of processing based on the first computation method according to an example embodiment of the present invention.

FIG. 14 is a diagram illustrating an example of a flow of processing based on the second computation method according to an example embodiment of the present invention.

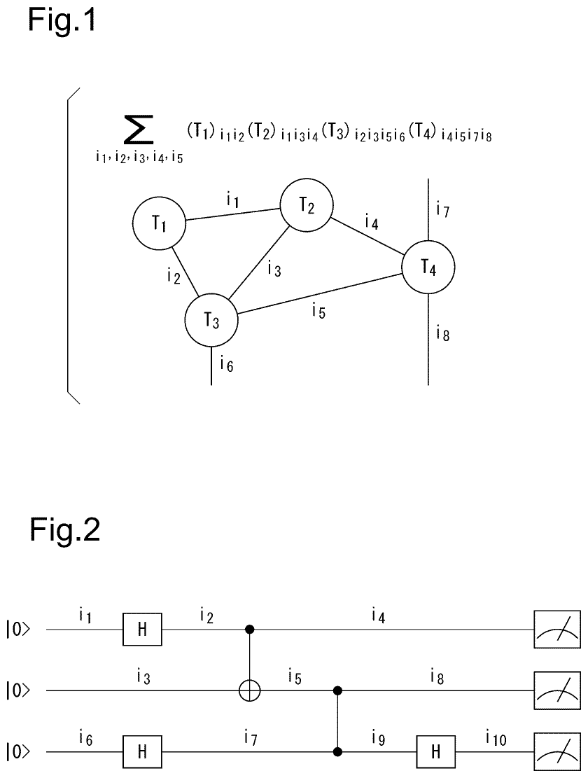

### EXAMPLE EMBODIMENT

### Example Embodiment

Hereinafter, an example embodiment of the present invention will be described in detail with reference to the drawings.

In a simulation of a quantum circuit that uses an approximation of a tensor network, there is a method of representing a quantum state in a state called a matrix product state and approximating it by a method called low-rank approximation. In the present example embodiment, the quantum circuit is a model indicating computation by a quantum computer. Quantum circuits are described by the states of qubits and the quantum gate operations applied to the qubits.

### [Matrix Product State]

A matrix product state represents coefficients representing superposition of quantum states using a product of matrices. A general N-qubit quantum state Y′ is expressed by Expression (1) using bra-ket notation.

$$\begin{matrix}[ Math . 1 ] & \\ \vert Ψ 〉 = {\sum }_{{i}_{1} , {i}_{2} , … , {i}_{N}} {Ψ}_{{i}_{1} {i}_{2} … {i}_{N}} \vert {i}_{1} {i}_{2} … {i}_{N} 〉 & ( 1 )\end{matrix}$$

Based on this notation, for example, the quantum state when three qubits are present is represented as in Expression (2).

$$\begin{matrix}[ Math . 2 ] & \\ \vert Ψ 〉 = {Ψ}_{000} \vert 000 〉 + {Ψ}_{100} \vert 100 〉 + {Ψ}_{010} \vert 010 〉 + {Ψ}_{110} \vert 110 〉 + {Ψ}_{001} \vert 001 〉 + {Ψ}_{101} \vert 101 〉 + {Ψ}_{011} \vert 011 〉 + {Ψ}_{111} \vert 111 〉 & ( 2 )\end{matrix}$$

Here, the state of each qubit is represented by an index indicated in the ket|·>. For example, in the state |011>, the states of the first, second, and third qubits are 0, 1, and 1, respectively. The matrix product state represents the coefficients Ψ_{i1i2 . . . iN} (i1 denotes i₁, and the same applies to the other indices) of a quantum state by a product of matrices. This product of matrices is shown in Expression (3).

$$\begin{matrix}[ Math . 3 ] & \\ {Ψ}_{{i}_{1} {i}_{2} … {i}_{N}} = {A}_{1} [ {i}_{1} ] {A}_{2} [ {i}_{2} ] … {A}_{N} [ {i}_{N} ] & ( 3 )\end{matrix}$$

In Expression (3), the indices i₁, i₂, . . . , and in on the left-hand side respectively correspond to the arguments i₁, i₂, . . . , and i_{N} on the right-hand side. The symbols A₁, A₂, . . . , and A_{N} on the right side are matrices.

Singular value decomposition is used to convert a quantum state into a matrix product state. Singular value decomposition converts a complex matrix into a product of two unitary matrices and a singular value matrix.

A singular value matrix is a matrix containing positive real numbers as diagonal elements. Singular value decomposition of a complex matrix A with M rows and N columns is expressed by Expression (4).

$$\begin{matrix}[ Math . 4 ] & \\ A = U \sum {V}^{†} & ( 4 )\end{matrix}$$

where U is a unitary matrix with M rows and M columns, and V is a unitary matrix with N rows and N columns. The dagger symbol (†) after a matrix denotes the Hermitian conjugate. The symbol Σ is a singular value matrix, which is a matrix with M rows and N columns containing positive real numbers as diagonal elements. When the singular value matrix is expressed as a mathematical expression, it can be expressed by Expression (5).

$$\begin{matrix}[ Math . 5 ] & \\ \begin{matrix}Σ = ( \begin{matrix}{Σ}_{r \times r} & {0}_{r \times ( N - r )} \\ {0}_{( M - r ) \times r} & {0}_{( M - r ) \times ( N - r )}\end{matrix} ) , \\ r = rank ( A ) , \\ {Σ}_{r \times r} = diag ( {σ}_{1} , {σ}_{2} , ⋯ , {σ}_{r} ) , {σ}_{1} \geq {σ}_{2} \geq ⋯ \geq {σ}_{r}\end{matrix} & ( 5 )\end{matrix}$$

These positive real numbers σ₁, σ₂, . . . , σᵣ are referred to as singular values. Here, r represents the rank of the matrix A. The symbol Σ_{r×r} represents a partial matrix with r rows and r columns, which is a part of Σ in which singular values that are not zero are arranged in descending order. The symbol 0_{r×(N-r)} or the like represents a matrix with r rows and (N−r) columns whose elements are all zero.

### [Data Reduction by Singular Value Decomposition, and Low-Rank Approximation]

If the rank of the original matrix A is smaller than M and N, as shown in Expression (6), the original matrix A can be reconstructed using the matrix Σ_{r×r} in which the singular values are arranged, while reducing the number of matrix elements obtained from the singular value decomposition.

$$\begin{matrix}[ Math . 6 ] & \\ A = {U}_{M \times r} {Σ}_{r \times r} {V}_{r \times N}^{†} & ( 6 )\end{matrix}$$

where U_{M×r} is a submatrix using up to r columns of U, and V^{†}_{r×N} is a submatrix using up to r rows of V^{†}. When the rank of the original matrix A is significantly smaller than each of the number of rows M and the number of columns N, the effect of reducing the number of matrix elements by singular value decomposition is particularly large.

Furthermore, the number of matrix elements can also be reduced by ignoring the smaller singular values among the singular values arranged in descending order in the singular value matrix Σ_{r×r}. This operation corresponds to approximation that reduces the rank of the original matrix by reducing the number of singular values. Therefore, this operation is called low-rank approximation.

For example, it is determined in advance to retain the singular values of the original matrix A until the ratio of the sum of the singular values to the sum of the singular values of the original matrix reaches a predetermined ratio (e.g., 95%). As a result, in the case where k (<r) singular values are used, the result of the low-rank approximation is expressed as Expression (7).

$$\begin{matrix}[ Math . 7 ] & \\ A ≃ {U}_{M \times k} {Σ}_{k \times k} {V}_{k \times N}^{†} & ( 7 )\end{matrix}$$

As a result, the inequality expressed by Expression (8) is established.

$$\begin{matrix}[ Math . 8 ] & \\ 0.95 \times {\sum }_{i = 1}^{r} {σ}_{i} \leq {\sum }_{i = 1}^{k} {σ}_{i} \leq {\sum }_{i = 1}^{r} {σ}_{i} & ( 8 )\end{matrix}$$

### [Approximate Simulation of Quantum Computer Using Matrix Product State and Low-Rank Approximation]

Using a matrix product state and low-rank approximation, a quantum circuit can be approximately simulated using a tensor network.

The quantum state handled in the simulation of a quantum circuit is superposition of a plurality of states. For example, in the case of 3 qubits, 8 (=2³) states are superimposed, as indicated by Expression (9).

$$\begin{matrix}[ Math . 9 ] & \\ \vert Ψ 〉 = {Ψ}_{000} \vert 000 〉 + {Ψ}_{100} \vert 100 〉 + {Ψ}_{010} \vert 010〉 + {Ψ}_{110} \vert 110 〉 + {Ψ}_{001} \vert 001 〉 + {Ψ}_{101} \vert 101 〉 + {Ψ}_{011} \vert 011 〉 + {Ψ}_{111} \vert 111 〉 & ( 9 )\end{matrix}$$

This quantum state can be expressed as a row vector by Expression (10).

$$\begin{matrix}[ Math . 10 ] & \\ ( {Ψ}_{100} , {Ψ}_{100} , {Ψ}_{010} , {Ψ}_{110} , {Ψ}_{001} , {Ψ}_{101} , {Ψ}_{011} , {Ψ}_{111} ) & ( 10 )\end{matrix}$$

In order to convert the quantum state indicated by Expression (10) into a matrix product state, as indicated by Expression (11), first, each row is converted into a matrix with two rows respectively corresponding to states with a first qubit of 0 and states with a first qubit of 1.

$$\begin{matrix}[ Math . 11 ] & \\ ( \begin{matrix}{Ψ}_{000} & {Ψ}_{010} & {Ψ}_{001} & {Ψ}_{011} \\ {Ψ}_{100} & {Ψ}_{010} & {Ψ}_{101} & {Ψ}_{111}\end{matrix} ) & ( 11 )\end{matrix}$$

First, in order to express the first qubit in a matrix product state, the obtained matrix with two rows shown in Expression (11) is set as a matrix A as shown in Expression (12).

$$\begin{matrix}[ Math . 12 ] & \\ A = ( \begin{matrix}{Ψ}_{000} & {Ψ}_{010} & {Ψ}_{001} & {Ψ}_{011} \\ {Ψ}_{100} & {Ψ}_{010} & {Ψ}_{101} & {Ψ}_{111}\end{matrix} ) & ( 12 )\end{matrix}$$

The singular value decomposition described above is performed on the matrix A as expressed in Expression (13).

$$\begin{matrix}[ Math . 13 ] & \\ A = U Σ {V}^{†} & ( 13 )\end{matrix}$$

At this time, the matrix U corresponds to the matrix product state of the first qubit, and the matrix ΣV^{†} corresponds to the state of the second and subsequent qubits. When singular value decomposition is further performed on the obtained matrix ΣV^{†}, the matrix product states of the second and third qubits can be extracted.

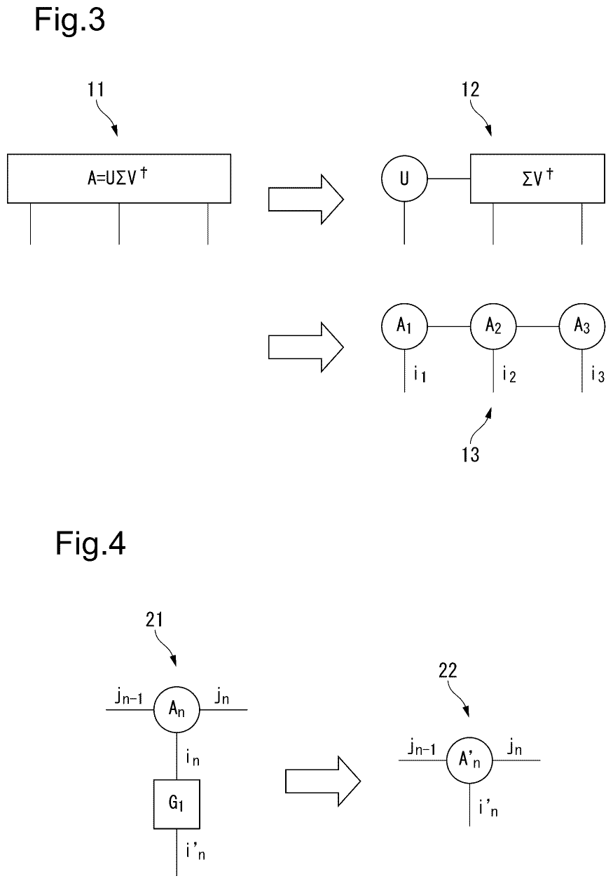

These operations are represented by a tensor network graph as illustrated in FIG. 3. FIG. 3 is a diagram illustrating an example of a tensor network graph corresponding to performing singular value decomposition to construct a matrix product state. A graph 11 in FIG. 3 illustrates a state in which all the coefficients of the states of 3 qubits are represented as a matrix. A graph 12 is a graph in which the first qubit is represented by a matrix product state by performing singular value decomposition on the graph 11. Furthermore, when singular value decomposition of a matrix representing the states of the second and third qubits is performed, a graph 13 is obtained.

The symbols A₁, A₂, and A₃ surrounded by circles in the graph 13 represent the respective matrix product states. The lines extending downward from A₁, A₂, and A₃ surrounded by circles each represent an argument (i₁ for A₁ [i₁]; the same applies to the other indices) of a matrix product state representing a 0 or 1 state of each qubit. When a quantum circuit is simulated by a tensor network, the state of each qubit is represented by a matrix product state.

In a quantum circuit, quantum gate operations are performed on qubits, and the quantum gate operations are classified based on the number of qubits they act on. Examples of the quantum gate operations include a 1-qubit gate operation, which performs a quantum gate operation on only one qubit, and a 2-qubit gate operation, which performs a quantum gate operation on two qubits.

When a 1-qubit gate operation is calculated by a simulation using a tensor network, the graph illustrated in FIG. 4 is obtained. FIG. 4 is a diagram illustrating an example of a tensor network graph corresponding to performing a 1-qubit gate operation on a matrix product state. A graph 21 illustrates that a tensor (Aₙ)ᵢₙⱼₙ₋₁ⱼₙ (in denotes iₙ; the same applies to the other indices) corresponding to the matrix product state Aₙ[iₙ] of the qubit represented by a circle, and a tensor (G₁)_{ini′n} (in denotes iₙ; the same applies to the other indices) corresponding to a quantum gate operation G₁ represented by a rectangle are contracted. A graph 22 illustrates a tensor (Aₙ′)_{i′njn-1jn} (i′n denotes i′ₙ; the same applies to the other indices) corresponding to the matrix product state A′ₙ[i′ₙ] obtained as a result of this contraction. That is, FIG. 4 illustrates that, as a result of taking this contraction, the tensor (Aₙ)ᵢₙⱼₙ₋₁ⱼₙ corresponding to the matrix product state Aₙ[iₙ] has been updated to the tensor (Aₙ′)_{i′njn-1jn} (i′n denotes i′ₙ; the same applies to the other indices) corresponding to the matrix product state A′ₙ[i′ₙ], as illustrated in Expression (14).

$$\begin{matrix}[ Math . 14 ] & \\ {\sum }_{{i}_{n}} {( {A}_{n} )}_{{i}_{n} {j}_{n - 1} {j}_{n}} {( {G}_{1} )}_{{i}_{n} {i}_{n}^{′}} = {( {A}_{n}^{′} )}_{{i}_{n}^{′} {j}_{n - 1} {j}_{n}} & ( 14 )\end{matrix}$$

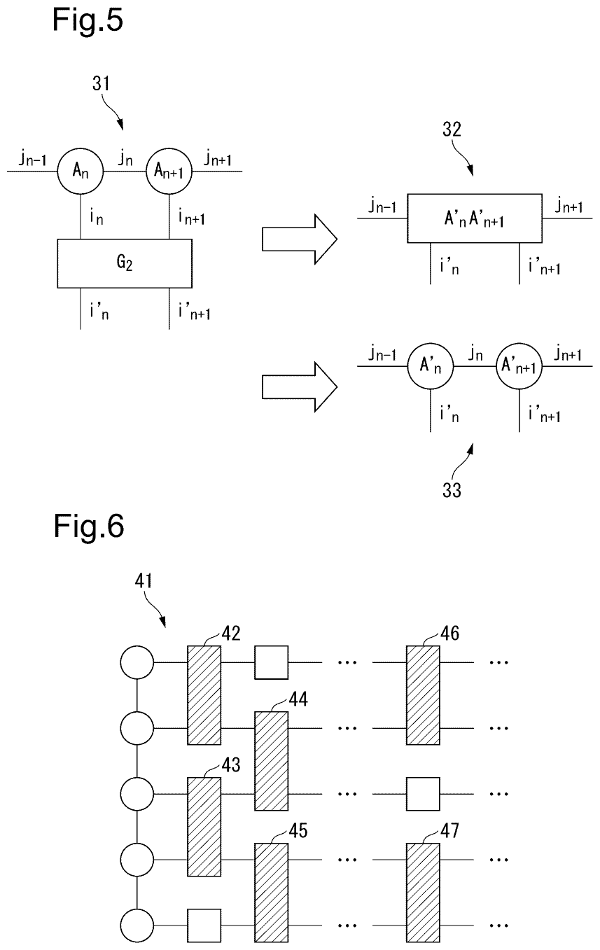

Next, a method of tensor contraction operation corresponding to performing a 2-qubit gate operation will be described. FIG. 5 is a diagram illustrating an example of a tensor network graph corresponding to performing a 2-qubit gate operation on a matrix product state. A graph 31 illustrates that the two qubits represented by circles (i.e., the tensor (Aₙ)ᵢₙⱼₙ₋₁ⱼₙ (in denotes iₙ; the same applies to the other indices) corresponding to the matrix product state Aₙ[iₙ] and the tensor (Aₙ+1)_{in+1 jnjn+1} (in+1 denotes iₙ₊₁; the same applies to the other indices) corresponding to the matrix product state Aₙ₊₁[ᵢₙ₊₁], and the tensor (G₂)_{inin+1in′in+1}′ (in denotes iₙ; the same applies to the other indices) corresponding to a 2-qubit gate operation G₂ represented by a rectangle are contracted. A graph 32 illustrates a tensor (Aₙ′Aₙ₊₁′)_{i′ni′n+1jn-1jn+1} (i′n denotes i′ₙ; the same applies to the other indices) corresponding to the states of two qubits obtained as a result of this contraction. That is, the upper part of FIG. 5 illustrates that, as a result of taking this contraction, the tensor (Aₙ)ᵢₙⱼₙ₋₁ⱼₙ (in denotes in; the same applies to the other indices) corresponding to the matrix product state Aₙ[iₙ] and the tensor (Aₙ₊₁)ᵢₙ₊₁ⱼₙⱼₙ₊₁) (in+1 denotes iₙ₊₁; the same applies to the other indices) corresponding to the matrix product state Aₙ₊₁[ᵢₙ₊₁] have been updated to the tensor (Aₙ′Aₙ₊₁′)_{i′ni′n+1jn-1jn+1} (i′n denotes i′ₙ; the same applies to the other indices) corresponding to the states of the two qubits, as shown in Expression (15).

$$\begin{matrix}[ Math . 15 ] & \\ {\sum }_{{i}_{n} , {i}_{n + 1} , {j}_{n}} {( {A}_{n} )}_{{i}_{n} {i}_{n - 1} {j}_{n}} {( {A}_{n + 1} )}_{{i}_{n + 1} {j}_{n} {j}_{n + 1}} {( {G}_{2} )}_{{i}_{n} {i}_{n + 1} {i}_{n}^{′} {i}_{n + 1}^{′}} = {( {A}_{n}^{′} {A}_{n + 1}^{′} )}_{{i}_{n}^{′} {i}_{n + 1}^{′} {j}_{n - 1} {j}_{n + 1}} & ( 15 )\end{matrix}$$

In the case of a 2-qubit gate operation, it is further necessary to convert the tensor (Aₙ′Aₙ₊₁′)_{i′ni′n+1jn-1jn+1′} (i′n denotes i′ₙ; the same applies to the other indices) corresponding to the states of two qubits into 1-qubit matrix product states by singular value decomposition. A graph 33 is obtained as a result of this conversion into matrix product states.

### [Effect of Approximate Simulation of Quantum Computer]

If singular value decomposition does not involve low-rank approximation, a simulation of a quantum circuit can be exactly performed. However, a simulation of a quantum circuit may handle superposition of an exponentially larger number of states. Therefore, in a case where a simulation is performed using a normal personal computer (PC) or the like, the memory may be insufficient. By using low-rank approximation when converting the states of two qubits to 1-qubit matrix product states, the simulation is performed while reducing the memory required to represent the state of qubits. For a quantum gate operation applied to three or more qubits, similarly to the case of two qubits, it is only required to perform tensor contraction, convert the result to matrix product states, and then perform low-rank approximation.

By combining tensor contraction, matrix product states, and low-rank approximation in a tensor network graph in this manner, it is possible to reduce the amount of computation when a simulation of a quantum circuit is calculated according to the order of quantum gate operations.

### [Problem of Approximate Simulation of Quantum Computer]

However, in a case where a simulation of a quantum circuit is performed by combining tensor contraction, matrix product states, and low-rank approximation, low-rank approximation is performed every time a multi-qubit gate is applied. Therefore, if a large number of quantum gate operations are performed, the accuracy of the simulation decreases.

With reference to FIG. 6, the decrease in the accuracy of the simulation in the case where low-rank approximation is performed every time a multi-qubit gate operation is performed will be described. FIG. 6 illustrates a 5-qubit quantum computer simulation by a graph 41 of a tensor network. In the graph 41, the quantum gate operations in which low-rank approximation is performed are represented by shaded rectangles (rectangles 42, 43, 44, 45, 46, and 47). In the example illustrated in FIG. 6, low-rank approximation is performed every time for gates that act on a plurality of qubits, such as those that perform a 2-qubit gate operation. Therefore, the accuracy of the simulation of a quantum computer decreases every time low-rank approximation is performed.

### [Pure State]

A state in quantum mechanics is classified as either a pure state, which is a single state in the context of quantum mechanics, or a mixed state, which is a state in which a plurality of these states are combined. Since it is difficult to create an exactly pure state in an actual quantum computer that is not a simulation, a mixed state is created. On the other hand, most of the states handled in simulations of quantum circuits are pure states.

[Probability that a State is Observed]

In quantum mechanics, the probability that a certain state |Ψ> is observed as |Ψ> is expressed by Expression (16).

$$\begin{matrix}[ Math . 16 ] & \\ {\vert 〈 Ψ \vert Ψ 〉 \vert}^{2} & ( 16 )\end{matrix}$$

where <·| is called a bra, and is the Hermitian conjugate of a ket. When the state is a pure state, the probability that the state will be observed is 1. Accordingly, for the pure state, the state inner product <Ψ|Ψ> is 1.

In addition, for the pure state, the norm of the state represented by Expression (17) is also 1.

$$\begin{matrix}[ Math . 17 ] & \\ ‖ \vert Ψ 〉 ‖ = \sqrt{〈 Ψ \vert Ψ 〉} & ( 17 )\end{matrix}$$

### [Von Neumann Entropy]

The von Neumann entropy S (ρ) is expressed by Expression (18) using a density operator ρ.

$$\begin{matrix}[ Math . 18 ] & \\ S ( ρ ) = - Tr ( ρlogρ ) & ( 18 )\end{matrix}$$

where the base of the logarithm is the base of the natural logarithm e or 2. The density operator p of a pure state typically handled by a quantum computer is expressed by Expression (19), where the quantum state is |Ψ>.

$$\begin{matrix}[ Math . 19 ] & \\ ρ = \vert Ψ 〉 〈 Ψ \vert & ( 19 )\end{matrix}$$

When the quantum state is a pure state in quantum mechanics, the von Neumann entropy is 0. In a simulation of a quantum circuit that does not involve approximation, if the initial state is a pure state, the state obtained as the simulation result is also a pure state. Therefore, in a simulation of a quantum circuit that does not involve approximation, the von Neumann entropy of the simulation result is also 0. However, when approximation such as low-rank approximation is performed and the simulation of a quantum circuit is not exact, the von Neumann entropy of the quantum state obtained by quantum gate operations will be larger than 0.

In the present example embodiment, low-rank approximation is performed based on a plurality of rules in the computation of a quantum circuit, and the state closest to a pure state is selected from among the obtained computation results. Specific examples of methods of selecting the state closest to a pure state include the following four methods. The first method is to obtain the probabilities of observing the states obtained from a plurality of computation results, and then select the solution whose probability is closest to 1. The second method is to select the solution in which the state inner product is closest to 1. The third method is to select the solution in which the norm of the state is closest to 1. The fourth method is to compare a plurality of computation results based on the von Neumann entropy and select the solution whose von Neumann entropy is closest to 0.

The rules for performing low-rank approximation include, for example, one that performs it for each quantum gate operation, and another that performs it for each group of quantum gate operations. Here, the reason why the computation related to performing low-rank approximation for each quantum gate operation, which has been mentioned as a problem of approximate computation, is also performed is that sometimes performing low-rank approximation for each quantum gate operation yields a computation result closer to that obtained without approximation than performing it for each group of quantum gate operations.

FIG. 6 illustrates a computation method for performing low-rank approximation for each quantum gate operation. Low-rank approximation is performed every time for gates that act on a plurality of qubits, such as those that perform a 2-qubit gate operation.

Examples of methods of performing low-rank approximation every time a group of quantum gate operations is performed include the following two types of methods. The two types of methods can both mitigate the influence of the decrease in accuracy caused by performing low-rank approximation for each quantum gate operation related to a plurality of qubits.

### [First Computation Method]

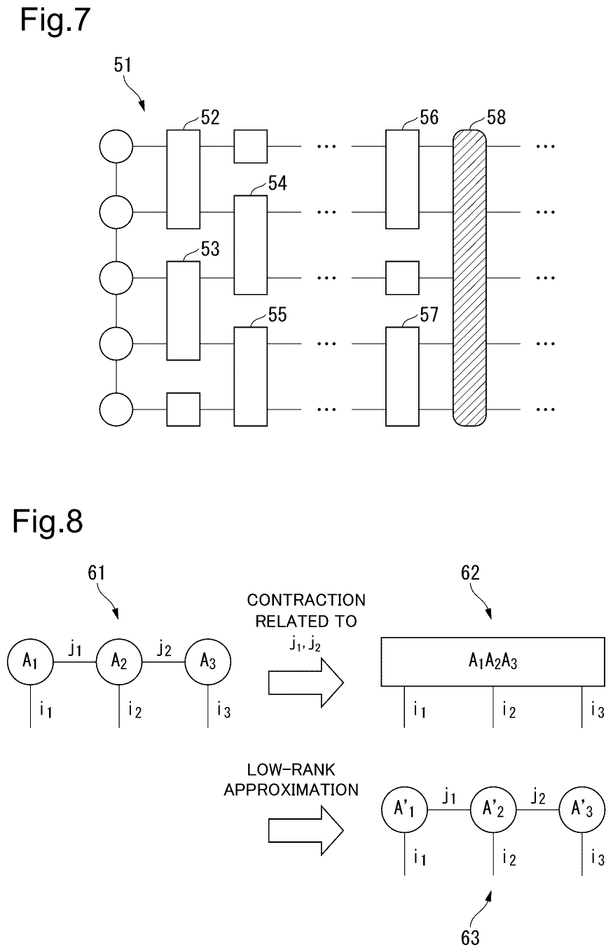

In a first computation method, low-rank approximation is performed after a group of quantum gate operations, which is a collection of a plurality of quantum gate operations. As described above, this procedure aims to mitigate the influence of the decrease in accuracy caused by low-rank approximation each time a quantum gate operation related to a plurality of qubits is performed. When the first computation method is represented by a tensor network graph similarly to FIG. 6, a graph 51 illustrated in FIG. 7 is obtained.

FIG. 7 is a diagram illustrating an outline of the first computation method, in which low-rank approximation is performed after a group of quantum gate operations without performing it for each quantum gate operation.

In the graph 51, low-rank approximation is not performed for the plurality of quantum gate operations in the middle. In FIG. 7, low-rank approximation is not performed for the quantum gate operations represented by unshaded rectangles 52, 53, 54, 55, 56, and 57. An operation is added that performs low-rank approximation on the state of each qubit after a group of quantum gate operations. The operation of collectively performing low-rank approximation on the state of each qubit is indicated by a shaded rounded rectangle 58 in FIG. 7.

FIG. 8 illustrates how to perform only the low-rank approximation corresponding to the rounded rectangle 58 in FIG. 7. FIG. 8 is a diagram illustrating an outline of a method of performing low-rank approximation from matrix product states without performing quantum gate operations. In a graph 61, a plurality of matrix product states are connected by edges. First, as illustrated in a graph 62, contraction related to indices corresponding to the edges connecting the matrix product states is performed.

Then, as illustrated in a graph 63, low-rank approximation can be performed together with singular value decomposition, similarly to the low-rank approximation in a quantum gate operation.

### [Second Computation Method]

Also in the second computation method, in order to mitigate the influence of the decrease in accuracy caused by low-rank approximation every time a quantum gate operation related to a plurality of qubits is performed, low-rank approximation is performed after a group of quantum gate operations, which is a collection of a plurality of quantum gate operations. However, unlike the first computation method, in the second computation method, low-rank approximation may be applied to some of the qubits instead of all.

In the second computation method, while quantum gate operations are being sequentially performed, low-rank approximation is not performed if the number of qubits related to the quantum gate operation is less than a specified number. Low-rank approximation is performed immediately before the number of qubits exceeds the specified number for the first time due to a certain quantum gate operation. When a quantum circuit is represented by a tensor network, this corresponds to performing low-rank approximation at a stage where the number of qubits related to a group of quantum gates connected with edges does not exceed a specified number.

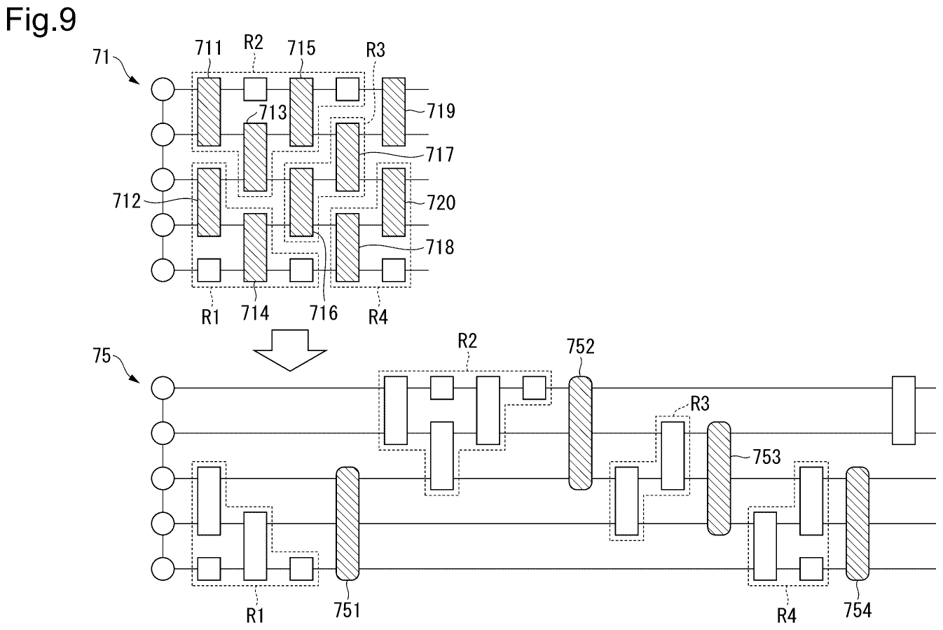

The second computation method will be described more specifically with reference to FIG. 9. FIG. 9 is a diagram illustrating an outline of the second computation method. FIG. 9 illustrates a method of performing low-rank approximation at a stage where the number of qubits related to a group of quantum gates connected with edges does not exceed a specified number (e.g., three), without performing it for each quantum gate operation.

A graph 71 represents a 5-qubit quantum circuit including a plurality of 2-qubit gate operations. In the graph 71, the shaded rectangles (rectangles 711 to 720) indicate performing low-rank approximation for each 2-qubit gate operation. In the quantum circuit illustrated in the graph 71, when viewed in order from the left, it can be seen that the number of qubits related to the quantum gate operations is three in each of the regions (regions R1, R2, R3, and R4) surrounded by broken lines. A region containing a group of quantum gates does not contain any quantum gate from another group. In the second computation method, low-rank approximation is not performed in the quantum gate operations included in a region surrounded by the broken line, but is performed immediately after all the quantum gate operations included in the region are completed.

To reflect these features, in the second computation method, as indicated by the graph 75, low-rank approximation is not performed in the quantum gate operations included in the regions surrounded by broken line (the regions R1, R2, R3, and R4), but is performed immediately after all the quantum gate operations in each region are completed, as indicated by the shaded rounded rectangles (rounded rectangles 751, 752, 753, and 754). The quantum gate operations are applied to each qubit in the same order as the groups of quantum gates appear in the circuit.

### [Configuration of Quantum Circuit Simulation Device 100]

A method of using a pure state in an approximate quantum circuit simulation using matrix product states and low-rank approximation will be described.

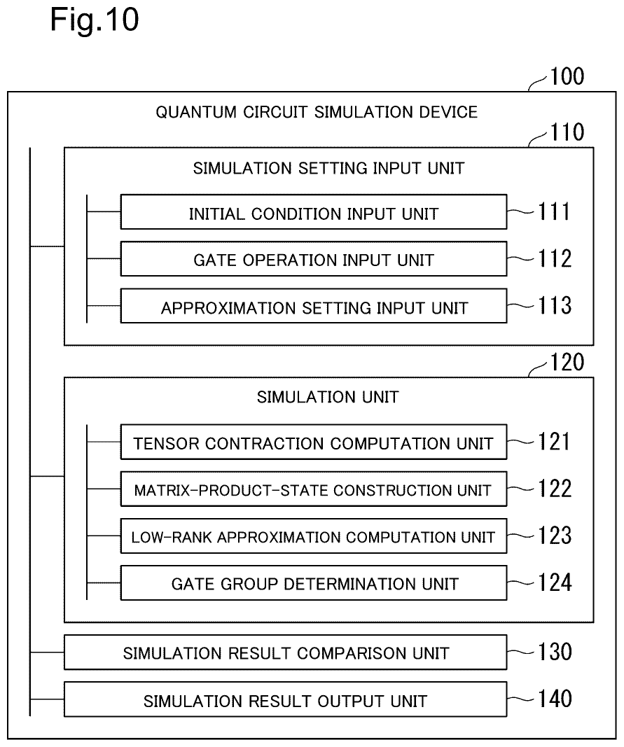

FIG. 10 is a block diagram illustrating an example of the configuration of a quantum circuit simulation device 100 according to the present example embodiment. The quantum circuit simulation device 100 is a device that performs an approximate quantum circuit simulation using matrix product states and low-rank approximation. The quantum circuit simulation device 100 includes a simulation setting input unit 110, a simulation unit 120, a simulation result comparison unit 130, and a simulation result output unit 140.

The simulation setting input unit 110 includes an initial condition input unit 111, a gate operation input unit 112, and an approximation setting input unit 113. The simulation setting input unit 110 acquires various types of information for simulating the input quantum circuit. These various types of information are input by, for example, an external information processing apparatus, an operation by a user, or the like.

Qubit initial state information is input to the initial condition input unit 111. The qubit initial state information is information indicating the states of qubits before a quantum gate operation is performed. This state of qubits may be a state in which the states of all the qubits are 0 or 1, or may be a state obtained from a simulation of another quantum circuit or computation by another quantum computer.

Quantum gate information is input to the gate operation input unit 112. The quantum gate information is information indicating the quantum gates constituting the quantum circuit. The gate operation input unit 112 acquires pieces of quantum gate information in the order in which the quantum gates are applied in the quantum circuit. Depending on the purpose of the simulation, quantum gate information indicating all the quantum gates may be input before performing the simulation of the quantum circuit, or quantum gate information indicating quantum gates to be sequentially applied may be input.

Approximation setting information is input to the approximation setting input unit 113. The approximation setting information is information indicating one or more settings related to low-rank approximation performed in the middle of the simulation. The approximation setting information includes, for example, information indicating a setting related to a method that is not the computation method in which low-rank approximation is performed for each quantum gate operation. The approximation setting information includes, for example, information indicating how many multi-qubit quantum gate operations should be performed between each low-rank approximation in the first computation method.

In addition, the approximation setting information includes information specifying that low-rank approximation should be performed before the number of qubits related to a group of quantum gates connected with edges reaches a certain number in the second computation method.

Furthermore, the approximation setting information includes information indicating that elements should be extracted so that the sum of diagonal elements of the singular value matrix becomes equal to or more than a certain percentage (equal to or more than 95%, equal to or more than 99%, etc.) in low-rank approximation. Note that the approximation setting information is not limited thereto.

The simulation unit 120 includes a tensor contraction operation unit 121, a matrix-product-state construction unit 122, a low-rank approximation computation unit 123, and a gate group determination unit 124. The simulation unit 120 simulates a quantum circuit.

The tensor contraction operation unit 121 performs contraction operations in a tensor network based on the states of qubits and information (quantum gate information) indicating the quantum gate operations to be applied to the qubits. This contraction operation corresponds to a quantum gate operation.

The matrix-product-state construction unit 122 constructs a matrix product state from the state of a qubit that is not represented by a matrix product state.

The low-rank approximation computation unit 123 performs low-rank approximation when forming a matrix product state that involves low-rank approximation.

In the second computation method, the gate group determination unit 124 determines a group of quantum gates.

The simulation result comparison unit 130 compares the results of a simulation of a quantum circuit obtained by a plurality of computation methods. The simulation result comparison unit 130 obtains any one of the probability of being observed, the state inner product, the norm of the state, and the von Neumann entropy for the simulation results of the quantum circuit, and uses it for comparison.

The simulation result output unit 140 outputs the one of the obtained results closest to a pure state as the simulation result of the quantum circuit. The result closest to a pure state is obtained by one of the following methods: selecting the solution whose probability of being observed is closest to 1, selecting the solution whose state inner product is closest to 1, selecting the solution whose norm of state is closest to 1, or selecting the solution whose von Neumann entropy is closest to 0.

The quantum circuit simulation device 100 is, for example, a personal computer (PC). Each of the functional units included in the quantum circuit simulation device 100 is implemented, for example, by a central processing unit (CPU) loading a program read from a read only memory (ROM) into a random access memory (RAM) and executing processing according to the program. Note that the quantum circuit simulation device 100 may be implemented as a virtual server. The functional units included in the quantum circuit simulation device 100 may be distributed and included in a plurality of servers. The quantum circuit simulation device 100 may be implemented as a cloud server.

### [Simulation Method]

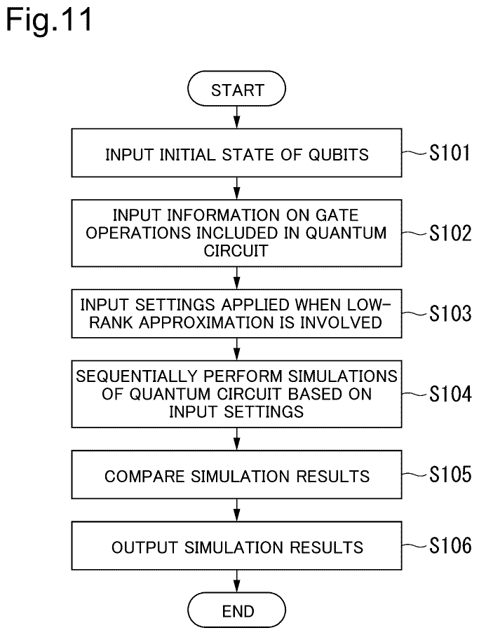

FIG. 11 is a diagram illustrating an example of a flow of processing based on a simulation method according to the present example embodiment. The simulation method illustrated in FIG. 11 is performed by the quantum circuit simulation device 100.

First, qubit initial state information indicating the initial state of qubits is input to the initial condition input unit 111 (step S101).

Quantum gate information (what gates are applied and in what order) on the quantum gate operations included in the quantum circuit to be simulated is input to the gate operation input unit 112 (step S102).

Thereafter, approximation setting information indicating the settings and conditions for performing low-rank approximation is input to the approximation setting input unit 113 (step S103). In step S103, setting is performed for a plurality of computation methods based on the input approximation setting information. The setting for a plurality of computation methods includes setting for a computation method for performing low-rank approximation for each quantum gate operation, setting for a computation method for performing low-rank approximation for each group of quantum gate operations, and the like.

Thus, the information for performing the simulation has been input.

The simulation unit 120 simulates a quantum circuit (step S104). In step S104, the simulation unit 120 performs a simulation based on each of the plurality of computation methods. As described above, the plurality of computation methods include a computation method for performing low-rank approximation for each quantum gate operation, and a computation method for performing low-rank approximation for each group of quantum gate operations.

Once the simulations run in step S104 are completed, the simulation result comparison unit 130 compares the results of a simulation of a quantum circuit obtained by a plurality of computation methods (step S105). From each of the simulation results provided by the plurality of computation methods, the simulation result comparison unit 130 calculates any one of the probability of being observed, the state inner product, the norm of the state, and the von Neumann entropy.

The simulation result comparison unit 130 selects the solution closest to a pure state from the results obtained by the plurality of computation methods based on the calculated quantity. According to the calculated quantity, the simulation result comparison unit 130 selects one of the solution whose probability of being observed is closest to 1, the solution whose state inner product is closest to 1, the solution whose norm of state is closest to 1, and the solution whose von Neumann entropy is closest to 0.

Therefore, in an approximate simulation of a quantum circuit in which a pure state is the starting state, the simulation result comparison unit 130 compares a plurality of simulation results different from each other in the approximation method based on the proximity to a pure state.

The simulation result output unit 140 outputs the result closest to a pure state among the simulation results based on the comparison result by the simulation result comparison unit 130 (step S106).

The quantum circuit simulation device 100 thus completes the simulation method.

Next, a specific computation method for simulating a quantum circuit will be described.

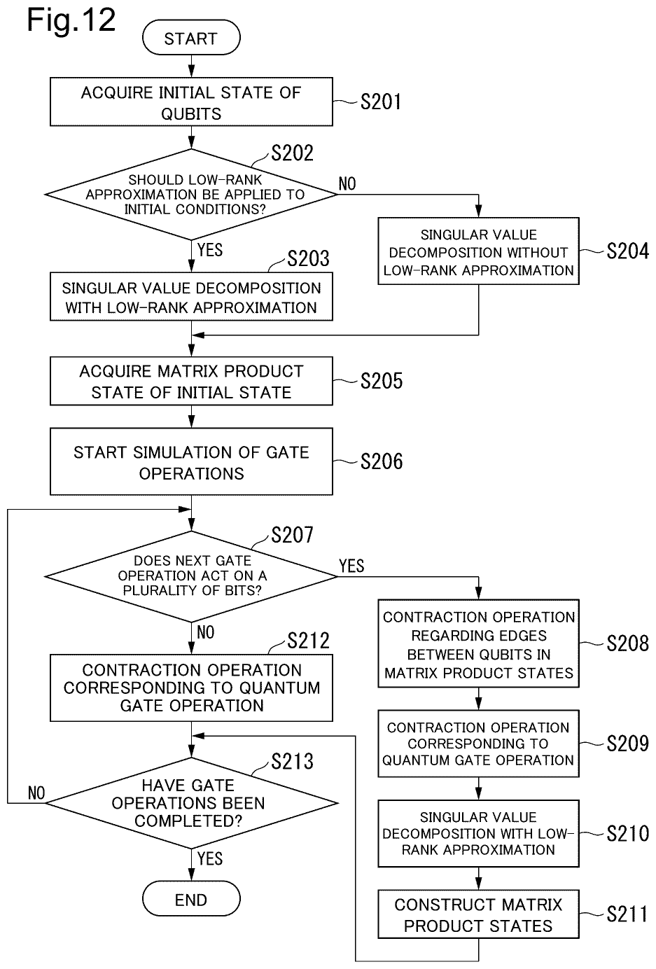

First, a computation method for performing low-rank approximation for each quantum gate operation will be described with reference to FIG. 12. FIG. 12 is a diagram illustrating an example of a flow of processing based on a computation method in a case where low-rank approximation is performed for each quantum gate operation according to the present example embodiment.

First, the simulation unit 120 obtains the qubit initial state information input to the initial condition input unit 111 (step S201). Subsequently, the simulation unit 120 determines whether to apply low-rank approximation to the initial state of the qubits based on the approximation setting information input to the approximation setting input unit 113 (step S202). When low-rank approximation is determined to be performed, the matrix-product-state construction unit 122 performs singular value decomposition on the initial state, and the low-rank approximation computation unit 123 performs low-rank approximation in the middle of the singular value decomposition (step S203). When it is determined that low-rank approximation is not to be performed, the matrix-product-state construction unit 122 performs singular value decomposition on the initial state without low-rank approximation (step S204).

A matrix product state of the initial state of the qubits is constructed by step S203 or step S204. The simulation unit 120 acquires the constructed matrix product state (step S205). At this stage, the setting of the initial condition of the simulation of the quantum circuit is completed.

Next, the simulation unit 120 starts to apply the quantum gate operations in the simulation of the quantum circuit and applies the gates sequentially (step S206). In the case where low-rank approximation is performed for each quantum gate operation, it is performed for each quantum gate operation related to a plurality of qubits. On the other hand, for 1-qubit gates, since the number of elements of the matrix representing the state does not increase even when contraction is performed for a quantum gate operation, low-rank approximation is not performed. Therefore, the simulation unit 120 determines whether the gate is a multi-qubit gate in each quantum gate operation (step S207).

If it is determined that the qubit gate is a multi-qubit gate, the tensor contraction operation unit 121 performs a contraction operation regarding the edges between qubits in matrix product states representing the states of the qubits at that time (step S208), and the tensor contraction operation unit 121 performs a contraction operation regarding a quantum gate operation (step S209). Thereafter, the matrix-product-state construction unit 122 and the low-rank approximation computation unit 123 perform singular value decomposition involving low-rank approximation (step S210), and the matrix-product-state construction unit 122 constructs matrix product states (step S211).

On the other hand, in the case where it is determined that the gate is not a multi-qubit gate but a 1-qubit gate, the tensor contraction operation unit 121 performs a contraction operation related to the quantum gate operation (step S212).

As the final stage of performing quantum gate operations, the simulation unit 120 determines whether all the quantum gate operations or low-rank approximation operations in the quantum circuit have been completed (step S213). If it is determined that the simulation has been completed, the simulation unit 120 ends the simulation of the quantum circuit. On the other hand, if the simulation unit 120 determines that the simulation has not been completed, the processing of step S207 is executed again, and the processing of step S207 and the subsequent steps are repeated until the quantum gate operations or low-rank approximation operations in the quantum circuit are completed.

Then, the simulation unit 120 ends the computation method for performing low-rank approximation for each quantum gate operation.

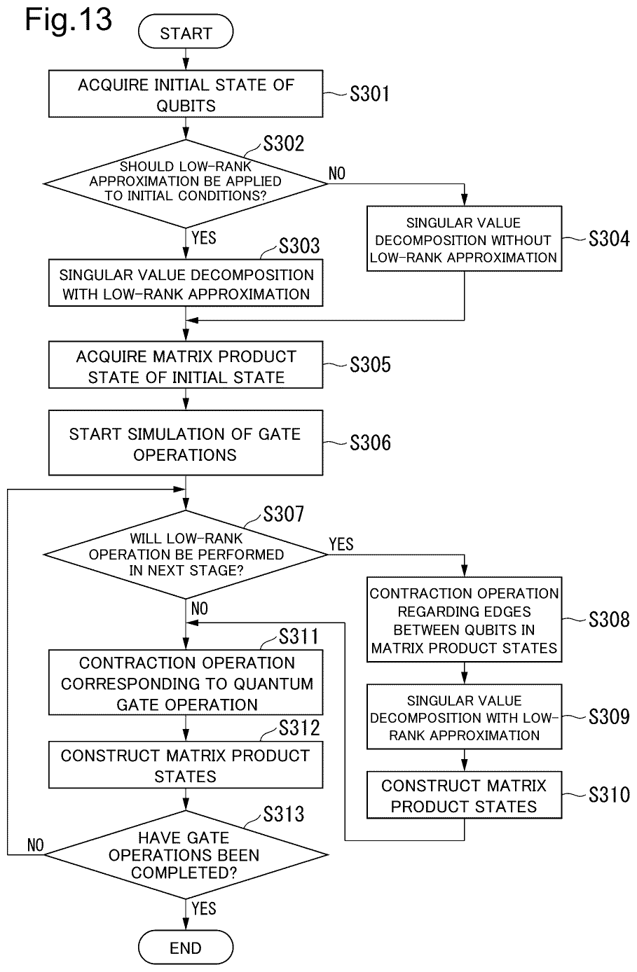

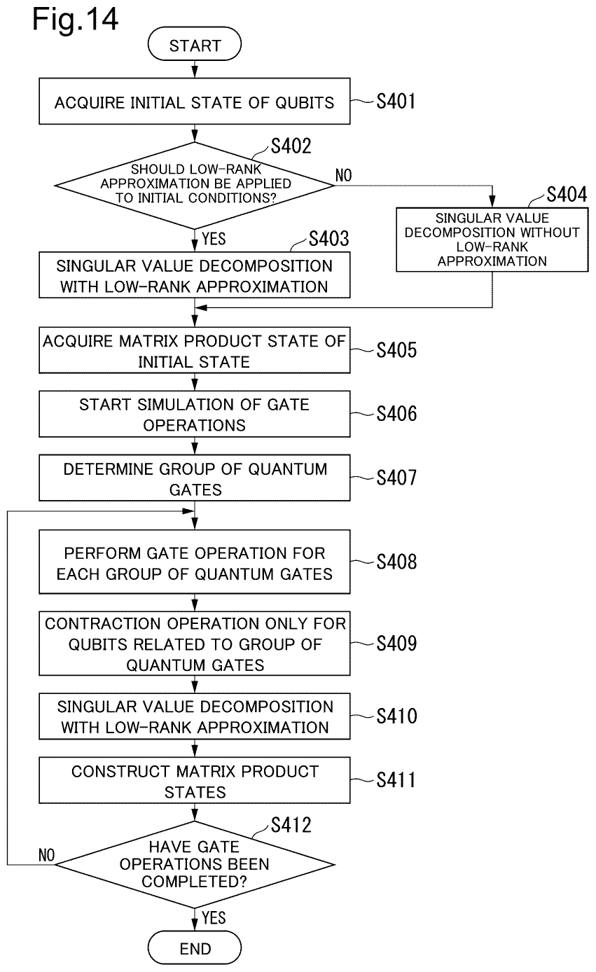

Next, with reference to FIGS. 13 and 14, examples of two types of computation methods for performing low-rank approximation every time a group of quantum gate operations is performed will be described.

### [First Computation Method]

FIG. 13 is a diagram illustrating an example of a flow of processing based on the first computation method according to the present example embodiment. The first computation method performs low-rank approximation every time a group of quantum gate operations is performed.

First, the simulation unit 120 obtains the qubit initial state information input to the initial condition input unit 111 (step S301). Subsequently, the simulation unit 120 determines whether to apply low-rank approximation to the initial state of the qubits based on the approximation setting information input to the approximation setting input unit 113 (step S302). When low-rank approximation is determined to be performed, the matrix-product-state construction unit 122 performs singular value decomposition on the initial state, and the low-rank approximation computation unit 123 performs low-rank approximation in the middle of the singular value decomposition (step S303). When it is determined that low-rank approximation is not to be performed, the matrix-product-state construction unit 122 performs singular value decomposition on the initial state without low-rank approximation (step S304).

A matrix product state of the initial state of the qubits is constructed by step S303 or step S304. The simulation unit 120 acquires the constructed matrix product state (step S305). At this stage, the setting of the initial condition of the simulation of the quantum circuit is completed.

Next, the simulation unit 120 starts to apply the quantum gate operations in the simulation of the quantum circuit and applies the gates sequentially (step S306). When a gate is applied, it is determined whether it is a stage where low-rank approximation should be performed immediately before the gate is applied, based on the information input by the approximation setting input unit 113 (step S307).

If it is determined that low-rank approximation should be performed, the tensor contraction operation unit 121 performs a contraction operation regarding the edges between qubits in matrix product states representing the states of the qubits at that time (step S308), and the matrix-product-state construction unit 122 and the low-rank approximation computation unit 123 perform singular value decomposition together with low-rank approximation (step S309). Thereafter, the matrix-product-state construction unit 122 constructs matrix product states (step S310).

Regardless of whether the matrix product state was obtained after low-rank approximation or no low-rank approximation was performed, the tensor contraction operation unit 121 performs a contraction operation corresponding to a quantum gate operation in the subsequent step (step S311). Thereafter, the matrix-product-state construction unit 122 constructs matrix product states of the qubits after the quantum gate operation (step S312).

As the final stage of performing quantum gate operations, the simulation unit 120 determines whether all the quantum gate operations or low-rank approximation operations in the quantum circuit have been completed (step S313). If it is determined that the simulation has been completed, the simulation unit 120 ends the simulation of the quantum circuit. On the other hand, if the simulation unit 120 determines that the simulation has not been completed, the processing of step S307 is executed again, and the processing of step S307 and the subsequent steps are repeated until the quantum gate operations or low-rank approximation operations in the quantum circuit are completed.

Thus, the simulation unit 120 ends the first computation method.

As described above, in the first computation method, a matrix product state involving low-rank approximation is constructed for every qubit included in the quantum circuit, each time a predetermined number of contraction operations are performed.

### [Second Computation Method]

FIG. 14 is a diagram illustrating an example of a flow of processing based on the second computation method according to the present example embodiment. The second computation method performs low-rank approximation every time a group of quantum gate operations is performed.

First, the simulation unit 120 obtains the qubit initial state information input to the initial condition input unit 111 (step S401). Subsequently, the simulation unit 120 determines whether to apply low-rank approximation to the initial state of the qubits based on the approximation setting information input to the approximation setting input unit 113 (step S402). When low-rank approximation is determined to be performed, the matrix-product-state construction unit 122 performs singular value decomposition on the initial state, and the low-rank approximation computation unit 123 performs low-rank approximation in the middle of the singular value decomposition (step S403). When it is determined that low-rank approximation is not to be performed, the matrix-product-state construction unit 122 performs singular value decomposition on the initial state without low-rank approximation (step S404).

A matrix product state of the initial state of the qubits is constructed by step S403 or step S404. The simulation unit 120 acquires the constructed matrix product state (step S405). At this stage, the setting of the initial condition of the simulation of the quantum circuit is completed.

Next, the simulation unit 120 starts to apply the quantum gate operations in the simulation of the quantum circuit (step S406). The gate group determination unit 124 determines a group of quantum gates so that the number of qubits related to the group of quantum gates connected by edges does not exceed a specified number (step S407).

Thereafter, the simulation unit 120 performs quantum gate operations for each group of quantum gates by applying the gates in the order in which they appear (step S408). The tensor contraction operation unit 121 performs contraction operations related to the qubits included in the quantum gate group (step S409). After the contraction operations for a group of quantum gate operations are performed, the matrix-product-state construction unit 122 and the low-rank approximation computation unit 123 perform singular value decomposition involving low-rank approximation (step S410). Then, the matrix-product-state construction unit 122 constructs a matrix product state (step S411).

As the final stage of performing quantum gate operations, the simulation unit 120 determines whether all the quantum gate operations in the quantum circuit have been completed (step S412). If it is determined that the simulation has been completed, the simulation unit 120 ends the simulation of the quantum circuit. On the other hand, if the simulation unit 120 determines that the simulation has not been completed, the processing of step S408 is executed again, and the processing of step S408 and the subsequent steps are repeated until the quantum gate operations in the quantum circuit are completed.

Thus, the simulation unit 120 ends the second computation method.

As described above, in the second computation method, in a tensor network indicating a quantum circuit, if the number of connected qubits will exceed a predetermined number by a contraction operation, a matrix product state involving low-rank approximation is constructed for the connected qubits immediately before the contraction operation.

As mentioned above, the tensor contraction operation unit 121 performs contraction operations in a tensor network corresponding to quantum gate operations based on the state of qubits and information indicating the quantum gate operations to be applied to the qubits.

The matrix-product-state construction unit 122 constructs a matrix product state from at least a qubit state obtained by a contraction operation by the tensor contraction operation unit 121.

When the matrix-product-state construction unit 122 constructs the matrix product state, the low-rank approximation computation unit 123 not only performs low-rank approximation for each multi-qubit quantum gate operation, but also at least performs it for each group of multi-qubit quantum gate operations.

In the present example embodiment, the computation method in which low-rank approximation is performed for each quantum gate operation, the first computation method, and the second computation method have been described as examples of computation methods for performing low-rank approximation based on a plurality of rules in the computation of a quantum circuit. However, the present invention is not limited thereto. Two or more of the computation method in which low-rank approximation is performed for each quantum gate operation, the first computation method, and the second computation method may be used, and the state closest to a pure state may be selected from their computation results. In addition, the computation methods for performing low-rank approximation may include a computation method other than the computation method in which low-rank approximation is performed for each quantum gate operation, the first computation method, and the second computation method.

If the second computation method is not used, the gate group determination unit 124 may be omitted from the configuration of the quantum circuit simulation device 100.

In the present example embodiment, an example case has been described where low-rank approximation is performed based on a plurality of rules in the computation of a quantum circuit, and the state closest to a pure state is selected from among the obtained computation results. However, the present invention is not limited thereto. Only one type of computation method may be used as the computation method for performing low-rank approximation. In that case, the process of selecting the state closest to a pure state among the computation results is omitted. Furthermore, in that case, the simulation result comparison unit 130 and the simulation result output unit 140 may be omitted from the configuration of the quantum circuit simulation device 100.

As described above, the simulation device (in the present example embodiment, the quantum circuit simulation device 100) according to the present example embodiment includes the tensor contraction operation unit 121, the matrix-product-state construction unit 122, and the low-rank approximation computation unit 123.

The tensor contraction operation unit 121 performs contraction operations in a tensor network corresponding to quantum gate operations based on the state of qubits and information indicating the quantum gate operations to be applied to the qubits.

The matrix-product-state construction unit 122 constructs a matrix product state from a qubit state obtained by a contraction operation by the tensor contraction operation unit 121.

The low-rank approximation computation unit 123 performs low-rank approximation for each of group of a plurality of quantum gate operations when the matrix-product-state construction unit 122 constructs a matrix product state.

With this configuration, since the simulation device (in the present example embodiment, the quantum circuit simulation device 100) according to the present example embodiment can perform low-rank approximation for each group of a plurality of quantum gate operations, it is possible to mitigate the influence of the decrease in simulation accuracy due to approximation when performing an approximate simulation of a quantum circuit based on a tensor network.

In addition, the simulation device according to the present example embodiment (the quantum circuit simulation device 100 in the present example embodiment) includes the simulation result comparison unit 130 and the simulation result output unit 140.

In an approximate simulation of a quantum circuit in which a pure state is the starting state, the simulation result comparison unit 130 compares a plurality of simulation results different from each other in the approximation method based on the proximity to a pure state.

The simulation result output unit 140 outputs the result closest to a pure state among the simulation results based on the comparison result by the simulation result comparison unit 130.

With this configuration, since the simulation device (in the present example embodiment, the quantum circuit simulation device 100) according to the present example embodiment can output the result closest to a pure state among a plurality of simulation results, it is possible to mitigate the influence of the decrease in simulation accuracy due to approximation when performing an approximate simulation of a quantum circuit based on a tensor network.

The units included in each device in the above example embodiment may be implemented by dedicated hardware or a memory and a microprocessor.

The units included in each device may be constituted by a memory and a central processing unit (CPU), and their functions may be achieved by loading a program for implementing the functions into the memory and executing the program.

A program for implementing the functions of the units included in each device may be recorded in a computer-readable recording medium, and the processing of each unit included in a control unit may be performed by causing a computer system to read and execute the program recorded in the recording medium. Note that the “computer system” here includes hardware such as an OS and peripheral devices.

In addition, the “computer system” is assumed to include a home page provision environment (or display environment) when the WWW system is used.

In addition, the “computer-readable recording medium” refers to a portable medium such as a flexible disk, a magneto-optical disk, a ROM, or a CD-ROM, or a storage device such as a hard disk built in the computer system. Furthermore, the “computer-readable recording medium” is assumed to include one that dynamically holds the program for a short period of time, such as a communication line in a case where the program is transmitted via a network such as the Internet or a communication circuit such as a telephone circuit, and another that holds the program for a certain period of time, such as a volatile memory inside the computer system serving as a server or a client in that case. The program may be for achieving a part of the functions described above, and the functions described above may be achieved in combination with a program already recorded in the computer system.

### REFERENCE SIGNS LIST

100 quantum circuit simulation device
110 simulation setting input unit
111 initial condition input unit
112 gate operation input unit
113 approximation setting input unit
120 simulation unit
121 tensor contraction operation unit
122 matrix-product-state construction unit
123 low-rank approximation computation unit
124 gate group determination unit
130 simulation result comparison unit
140 simulation result output unit

What is claimed is:

1. A simulation device comprising:
a tensor contraction operation circuit configured to perform a contraction operation in a tensor network corresponding to a quantum gate operation, based on a state of a qubit included in a quantum circuit and information indicating a quantum gate operation applied to the qubit;
a matrix-product-state construction circuit configured to construct a matrix product state from a state of a qubit obtained by a contraction operation by the tensor contraction operation circuit; and
a low-rank approximation computation circuit configured to perform low-rank approximation for each group of a plurality of quantum gate operations when the matrix-product-state construction circuit constructs a matrix product state.

2. The simulation device according to claim 1, wherein
a matrix product state involving low-rank approximation is constructed for every qubit included in the quantum circuit, each time a predetermined number of contraction operations are performed.

3. The simulation device according to claim 1, wherein,
in the tensor network indicating the quantum circuit, if the number of connected qubits will exceed a predetermined number by a contraction operation, a matrix product state involving low-rank approximation is constructed for the connected qubits immediately before the contraction operation.

4. A simulation device comprising:
a simulation result comparison circuit configured to compare a plurality of simulation results that use different approximation methods in an approximate simulation of a quantum circuit whose starting state is a pure state, the comparison being based on the proximity of each simulation result to a pure state; and
a simulation result output circuit configured to output the simulation result closest to a pure state among the plurality of simulation results based on a result of comparison by the simulation result comparison circuit.

5. The simulation device according to claim 4, wherein
the proximity to the pure state is defined as the proximity of a probability of being observed to 1.

6. The simulation device according to claim 4, wherein
the proximity to the pure state is defined as the proximity of a state inner product to 1.

7. The simulation device according to claim 4, wherein
the proximity to the pure state is defined as the proximity of a norm of a state to 1.

8. The simulation device according to claim 4, wherein
the proximity to the pure state is defined as the proximity of von Neumann entropy to 0.

9. A simulation method comprising:
a tensor contraction operation step of performing a contraction operation in a tensor network corresponding to a quantum gate operation, based on a state of a qubit included in a quantum circuit and information indicating a quantum gate operation applied to the qubit;
a matrix-product-state construction step of constructing a matrix product state from a state of a qubit obtained by a contraction operation by the tensor contraction operation step; and
a low-rank approximation computation step of performing low-rank approximation for each group of a plurality of quantum gate operations when the matrix-product-state construction step constructs a matrix product state.

10.-12. (canceled)
